(19) United States
(12) Patent Application Publication
(10) Pub. No.: US 2004/0145954 A1
(43) Pub. Date: Jul. 29, 2004

(54) Electrically tunable bandpass filters

(76) Inventor: Stanley S. Toncich, (US)

Correspondence Address: Qualcomm Incorporated, Patents Department, 5775 Morehouse Drive, San Diego, CA, 92121-1714, US

(21) Appl. No.: 10/260,080

(22) Filed: Sep. 27, 2002

Related U.S. Application Data
(60) Provisional application No. 60/325,701, filed on Sep. 27, 2001.

(51) Int. Cl. G11C 29/00

(52) U.S. Cl. 365/200

(57) ABSTRACT

A tunable bandpass filter includes at least one resonator having a reactance with a resonant frequency, a ferroelectric film having a dielectric constant with a value that changes with an applied electric field, and an electric field generating device for generating relatively constant electric fields of different strengths. The ferroelectric film is electrically coupled to the resonator so that the reactance of the resonator and therefore the resonant frequency of the resonator and the passband of the filter depends on the dielectric constant of the ferroelectric film. The electric field generating device is constructed and arranged to generate relatively constant electric fields within the ferroelectric film, thereby making the resonant frequency of the resonator and the passband of the filter a function of the strength of the relatively constant electric field.

### RELATED APPLICATIONS

This application claims the benefit of provisional U.S. Application Serial No. 60/325,701, entitled “ELECTRICALLY TUNABLE BANDPASS FILTERS,” filed Sep. 27, 2001, and provisional U.S. Application Serial No., entitled ELECTRONICALLY TUNABLE FILTERS/PASSIVES PROPOSAL, filed Sep. 23, 2002, both of which are incorporated herein by reference in their entirety for all purposes.

### BACKGROUND

Field

This invention relates generally to electronic filters. More specifically, this invention is directed to electrically tunable bandpass filters.

Due to increasingly crowded frequency allocations, modern wireless communication devices require increasingly stringent filtering specifications. This is particularly true for devices that operate in multiple modes and/or over multiple frequency bands. Devices now popularly in use employ fixed tuned bandpass filters (BPF) which have design tradeoffs. The design goals of low passband insertion loss (IL) and high close-in rejection conflict. Portions of the filter transfer function representing the edges of the passband have a finite slope (the passband cutoff is gradual rather than an ideal perfectly abrupt transition from ‘pass’ to ‘no-pass’). The more sharp the cut off required, the higher the order of the filter must be. Higher order filters are more bulky and have a greater IL than lower order filters and may require extensive turning to meet specifications. To meet the out-of-band rejection specifications, typical filter designs require a transmission zero, requiring a filter vendor to tune each filter during its manufacture. Multiple filters are typically required for multi-band, multi-mode operation. In spite of this, often filter specifications are not met, resulting in accepting non-compliant parts with increased IL or inadequate rejection, or using split band designs, which require extra switches and have greater IL.

Unlike a fixed tuned BPF, a tunable filter can be dynamically tuned to different frequency ranges within a specific band, and if sufficiently tunable, different frequency ranges within multiple bands. Tunable filters have several advantages over non-tunable filters. For example, tunable filters need not have a broad passband if the passband is dynamically adjustable. A narrow transfer function with high close-in rejection can be implemented with a lower order filter than can a wide transfer function with similar close-in rejection. Therefore, unlike a fixed tuned BPF, a tunable filter can be of a lower order and still meet desired rejection specifications. Lower order tunable filters are smaller in size, have a lower profile, lower IL, and can be built using lower precision components using a simpler fabrication processes, which in turn lowers cost. In addition, one filter topology can be optimized to cover multiple bands if the tuning range is wide enough. Thus multiple filter designs are no longer needed. Also, split-band designs along with the associated switches become unnecessary.

FIG. 1 shows a typical implementation of a top coupled BPF 100. One or more resonators 106 are coupled to an input 102 and an output 104 via capacitors 108. Other realizations are also possible. The resonators are constructed and arranged so as to have a reactance that has at least one resonant frequency. At frequencies below 200-300 MHz. the resonators can be constructed from discrete components (i.e. separate capacitors and inductors). Tuning involves changing the resonant frequency of the reactance by changing the values of the discrete components. At higher frequencies a more distributed layout is required because the inherent reactances of all circuit components become more significant at higher frequencies. At higher frequencies, resonators utilizing a monoblock design are commonly used.

A high frequency resonator is essentially a transmission medium with impedance discontinuities at both of its ends. Reflections at these discontinuities causes energy to build up within the resonator, a fraction of which is released during each cycle. A quality factor, Q, is defined as the ratio of the energy stored within the resonator to that dissipated during one cycle. Due to boundary conditions that must be obeyed by the electric and magnetic fields, only signals with wavelengths that divide the length of the resonator by certain discrete multiples will be maximally reflected and constructively interfere. These correspond to the resonant frequencies. Typically, the resonator is made sufficiently short such that only one resonant frequency exists within the frequency range to be filtered. Signals at other frequencies are increasingly transmitted to ground as their frequency difference from the resonance frequency increases, resulting in significant signal attenuation outside the passband.

The wavelength at a particular frequency within a particular transmission medium is a function of the reactance of that medium. The resonant frequency is changed by changing the length of the resonator as measured with respect to the wavelength of the signal such that the constructive interference underlying resonance occurs at the new resonance frequency. Electrical tuning can be accomplished either by changing the functional dependence of the local wavelength on the frequency or by changing the electrical length of the resonator.

The wavelength dependence on frequency within a transmission medium is a function of the reactance of the medium. This functional dependence of the wavelength is varied in YIG (Yttrium-Iron Garnet) resonators with the application of a variable magnetic field. But such resonators are expensive, require bulky magnetic field generating coils, and are unsuited for the low power, low profile, low cost requirements of mobile communication systems.

Another approach utilizes a bulk, single crystal ferroelectric (f-e) waveguide as a resonator, where an applied voltage across the body of the crystal is used to generate an electric field within the waveguide, thereby changing the dielectric constant of the crystal and hence its resonant frequency (see U.S. Pat. No. 5,617,104). However, the loss tangent of known f-e materials are poor compared to typical microwave ceramics. This means that the reactance of the material contains a non-negligible resistive component (i.e. an imaginary component to the dielectric constant), resulting in significant power loss via resistive heating of the material. As a result usage of bulk ferroelectric materials for resonators at GHz and sub-GHz frequencies are currently impractical for many applications. This does not preclude the use of ferroelectric films, but heretofore no prior art has disclosed or suggested the adaptation of such films to provide electrical tuning of electronic filters.

Further, bulk f-e resonators may require the application of rather high control voltages considering the relatively large geometries involved. As previously mentioned, electrical tuning can also be accomplished by changing the electrical length of the resonator. This is accomplished in the prior art via the use of varicaps in which one or more varactor diode is coupled to one end of the resonator. This arrangement electrically extends that end of the resonator because the capacitance of the varactor prevents that end from being either totally closed or totally open. Varactors provide a variable capacitance as a function of an applied dc voltage, and therefore changes the length of the resonator in response to changes in the voltage. But they are noisy, temperature dependent and have low Q's at UHF and above. They are also limited as to how they can be employed in a filter. They are too lossy to be put in parallel with a resonator and difficult to implement within a distributed design. In addition their capacitive values are relatively low and not very consistent from lot-to-lot.

### SUMMARY OF THE INVENTION

The invention is a tunable bandpass filter comprising: at least one resonator having a reactance with a resonant frequency, a ferroelectric f-e film having a dielectric constant with a value that changes with an applied electric field, and an electric field generating device for generating relatively constant electric fields of different strengths. The ferroelectric film is electrically coupled to the resonator so that the reactance of the resonator and therefore the resonant frequency of the resonator and the passband of the filter depends on the dielectric constant of the ferroelectric film. The electric field generating device is constructed and arranged to generate relatively constant electric fields within the ferroelectric film, thereby making the resonant frequency of the resonator and the passband of the filter a function of the strength of the relatively constant electric field.

### BRIEF DESCRIPTION OF THE DRAWINGS

FIG. 1 shows a typical implementation of a bandpass filter utilizing multiple coupled resonators.

FIG. 2 is a diagram of a microstrip resonator utilizing the f-e film.

FIG. 3 is a diagram of a first example of a stripline resonator utilizing the f-e film.

FIG. 4 is a diagram of a dielectric loaded waveguide resonator utilizing the f-e film.

FIG. 5 is a diagram of a second example of a stripline resonator utilizing the f-e film.

FIG. 6 is a diagram of an overlay capacitor coupled resonator utilizing the f-e film.

FIG. 7 is a diagram of an interdigitated filter topology.

FIG. 8 is a diagram of an interdigitated filter topology utilizing overlay capacitors.

FIG. 9 is a diagram of a combline filter topology utilizing overlay capacitors.

FIG. 10 is a table generally illustrating some of the design options, benefits and issues associated with a variety of f-e device designs.

### DETAILED DESCRIPTION

The relative permittivity, εᵣ, which determines the dielectric constant of a dielectric may be varied in f-e materials under the application of a slowly varying (“near DC”) electric field (E-field). And although the loss tangent of bulk f-e dielectrics is significant, that of applicable f-e thin or thick films fabricated on a wide range of microwave ceramics may be much better, approximating that of some commonly used microwave ceramics. Therefore, rather than use a varactor or bulk f-e dielectrics for electrical tuning, thin f-e films may be used to modify the local capacitance of the transmission medium and thereby provide an adjustable reactance that changes the resonant frequency of the resonator. When properly designed and fabricated, these f-e capacitors may provide a higher capacitance and Q than varactors at frequencies above 1 GHz. They are available as thin or thick films and are ideal for tuning distributed or lumped element resonators. Their electrical properties from lot-to-lot are also more consistent than that of varactors.

Thin/thick f-e films are widely used in high temperature superconductivity work, and there are several hundred of such known materials. Film thicknesses on the order of 0.1 μm to 1 mm are typical. Barium strontium titanate, BaₓSr₍₁₋ₓ₎TiO₃ (BSTO) is the most popular for room temperature operation where x is preferably between 0.3 and 0.7. Their tuning speed is about 0.3-1.0 μs for an applied constant E-field, so they are not modulated by a rf signals. An applied dc voltage V_{dc} is generally used to create the E-field. It is not uncommon to have films with Δεᵣ/ΔV_{dc}>3.

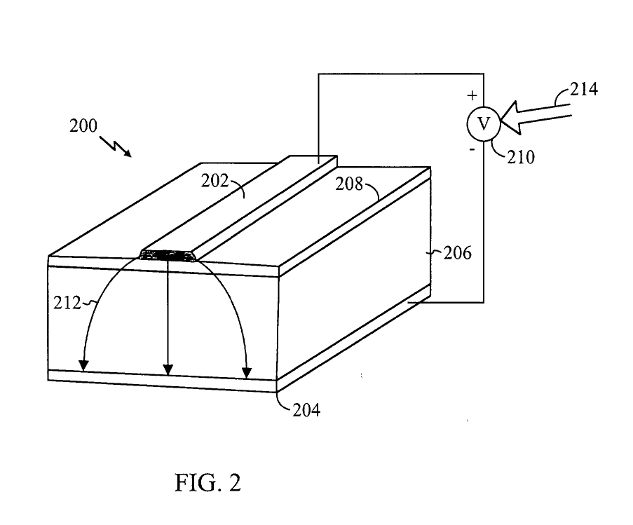

FIG. 2 is an example of a microstrip resonator 200 comprised of a microstrip filament layer 202, a ground plane 204, and a dielectric substrate 206. A f-e film layer 208 is positioned between the microstrip filament layer and the dielectric substrate. The wavelength of a propagated signal is a function of the dielectric constant of the transmission medium of the resonator and is therefore a function of the relative permittivity of the f-e film 208. A voltage applied by a dc voltage source 210 positively biases the microstrip filament 202 with respect to the ground plane 204, and creates an electric field (E-field) 212 across the f-e film that changes εᵣ of the film and therefore the resonant frequency of the resonator. The voltage is controlled by external control signal 214.

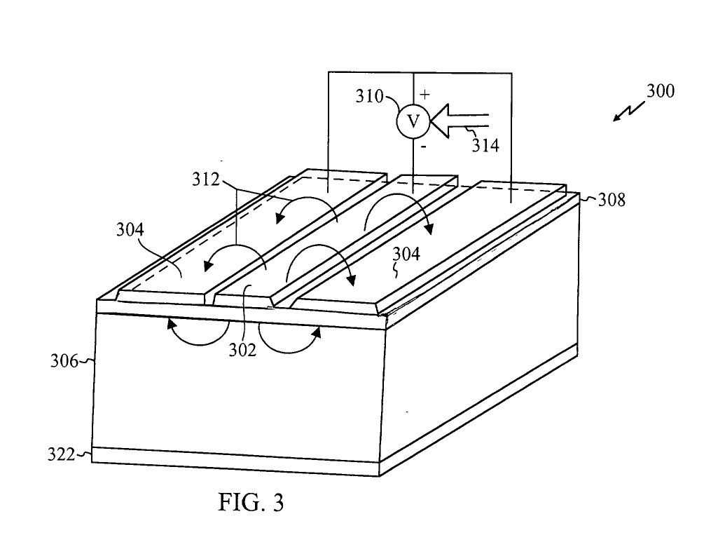

FIG. 3 is a first example of a coplanar waveguide 300 comprised of a central conductor 302, two grounded outer conductors 304, a ground plane 322, and a dielectric substrate 306. An f-e film layer 308 is positioned between the stripline conductors 302 and 304, and the dielectric substrate. A voltage applied by the dc voltage source 310 positively biases the central conductor with respect to the two outer conductors and creates an electric field (E-field) 312 across the f-e film, but in this case the choice of bias arrangement is better than that of FIG. 2 because the E-field 312 is more concentrated within the f-e film and is therefore greater for the same voltage and substrate thickness. The voltage is controlled by external control signal 314.

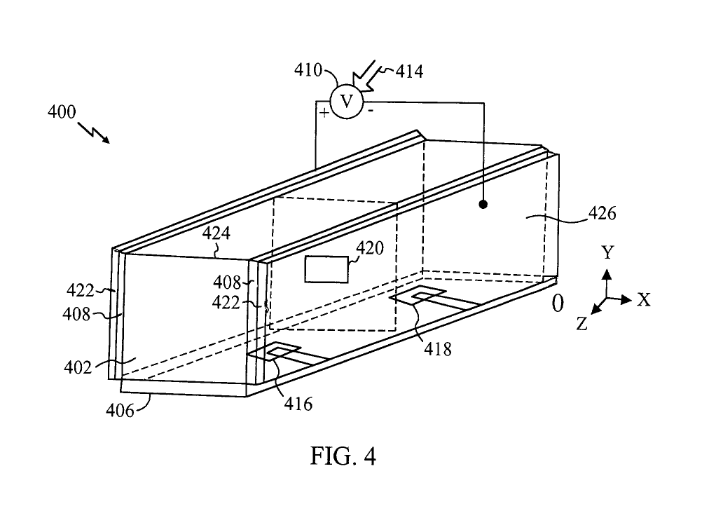

FIG. 4 is an example of a dielectric loaded waveguide (DLWG) resonator filter 400. An input signal introduced via input port 416 resonates at the resonant frequency within a first half of the waveguide 424 and is coupled via 2^{nd} order aperture 420 to a second half of the waveguide 426, which having the same resonant frequency, combine to form a second order filter. An output signal is taken via output port 418. The body of the filter, formed on substrate 406, is comprised of a high εᵣ dielectric 402. An f-c film 408, shown mounted on the surfaces parallel to the x-y plane at the aperture, is overlaid by conducting planes 422. A voltage applied between the two conducting planes 422 generates an E-field within the f-e film 408 that changes its reactance, resulting in a change of the resonant frequency within the waveguide. The voltage applied by dc voltage source 410 is controlled by control signal 414. The f-e film 408 and conducting planes 422 could also be mounted on the surfaces parallel to the x-y plane. With no external load, a DLWG resonator can provide a Q of about 1000 within the PCS band (i.e. around 2 GHz) with an I.L. of about 1.6 dB at a 3 dB bandwidth of 10 MHz.

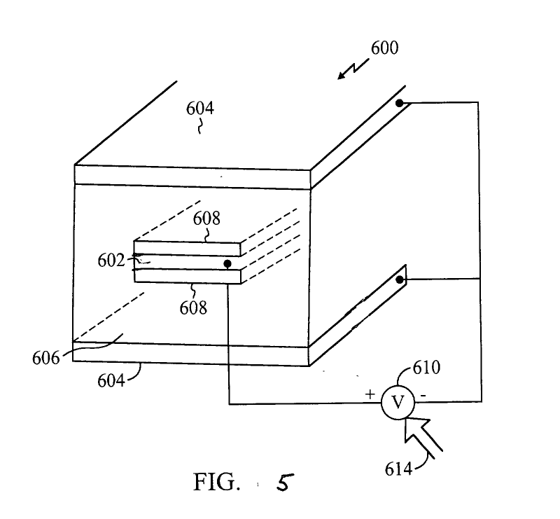

FIG. 5 shows a second example of a stripline resonator 600 comprised of a central conductor 602, two grounded outer conductors 604, and a dielectric substrate 606. The f-e film 608 is mounted between the central conductor 602 and the dielectric substrate 606. A dc voltage source 610 controlled by control signal 614 is applied between the central conductor 602 and the two outer conductors 604 so as to generate an E-field within the f-e film and thereby dynamically adjust the resonant frequency of the resonator 600. With no external load, a stripline resonator can provide a Q of about 750 within the PCS band with an I.L. of about 2.2 dB at a 3 dB bandwidth of 6 MHz.

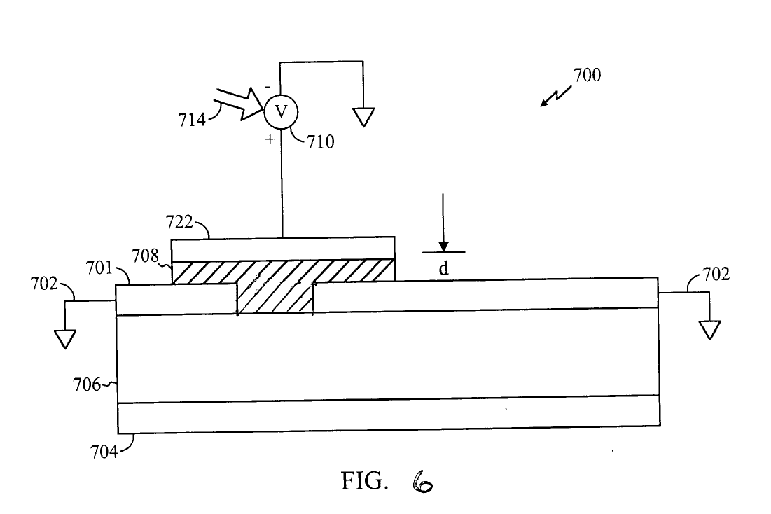

Filter tuning with f-e films can also be implemented according to a similar scheme as that described for tuning with varactors where tuning is accomplished by adjusting the effective electrical length of one end of the resonator. Instead of mounting the f-e film within the coax, stripline, or microstrip resonators as shown in FIGS. 2, 3 and 5, the film is coupled to the transmission medium by mounting it as an overlay capacitor as illustrated for the overlay capacitor coupled resonator 700 shown in FIG. 6. The basic resonator 701, which can be coaxial, stripline or microstrip, is mounted atop a ceramic substrate 706 with an underlying rf ground plane 704. An f-e film layer 708 of thickness d is positioned towards one end of the resonator and sandwiched between the resonator's grounded outer layer and an overlaid metal layer 722, thereby forming the overlay capacitor. Coupling to such a resonator can be achieved by either electromagnetic coupling, capacitive coupling, or by a direct tap into and out of the resonator (or filter) structure. F-e thin film layers of about 1 micro-meter seem to provide high dc R fields for a given (small) dc voltage. For an inductively coupled input signal, both ends of the resonators inner conductor 702 can be grounded as shown. A dc voltage source 710 controlled by control signal 714 generates the E-field used to adjust the capacitance of the overlay capacitor.

Direct f-2 thin film deposition can be done on some substrates, or with buffer layers on others. The packaging of an f-3 device may eliminate the need for a substrate.

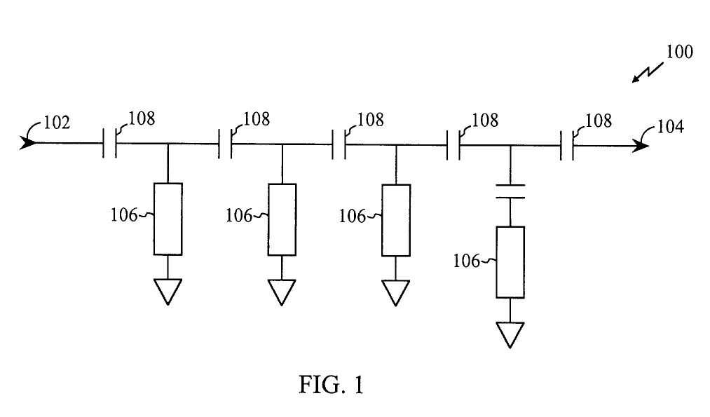

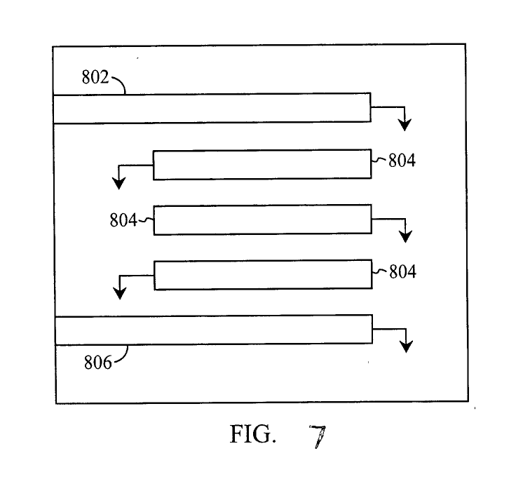

As shown in FIG. 1, multiple resonators can be electrically coupled to obtain a higher order filter with a filter transfer function that, while centered about the same resonant frequency as that of the resonator, has a more abrupt cutoff and a flatter peak than each individual resonator's transfer function. A number of different filter topologies utilizing different resonator types are possible. Popular topologies utilizing stripline and microstrip resonators include interdigitated filters, combline filters, and edge coupled and hairpin filters. FIG. 7 is the top view of an example of an interdigitated filter topology utilizing f-c film electrical tuning in which the wavelength-frequency relationship within the resonator is varied. The input signal via transmission line 802 is electromagnetically coupled to each resonator in turn as it travels across the resonators (vertically in the figure), and is output via transmission line 806. Each resonator has one capacitively loaded and one shorted end. The relative placement of which is alternated for adjacent filter. The resonance frequency of the resonator is electrically adjusted as described above for f-e film electrical tuning utilizing the wavelength-frequency relationship adjustment.

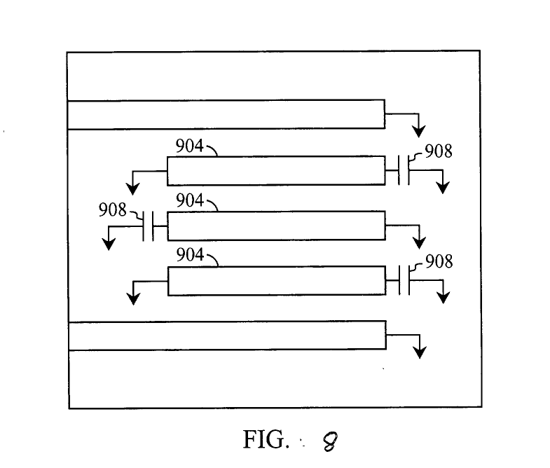

FIG. 8 shows the same topology as that of FIG. 7 but with tuning achieved via the use of overlay capacitors 908 coupled to what would otherwise have been the open end of the resonators 904.

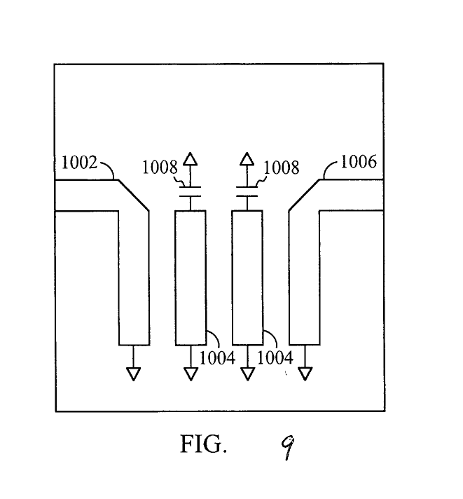

FIG. 9 is the top view of an example of a second order electromagnetically coupled planar combline filter topology utilizing overlay capacitors 1008. The signal input via transmission line 1002 is electromagnetically coupled to each resonator in turn as it travels across the resonators 1004 (horizontally in the figure), and is outputted via transmission line 1006. Such a filter may have a 10 mhz bandwidth in the PCS band. With a 20 mil thick MgO substrate, no buffer layer may be needed.

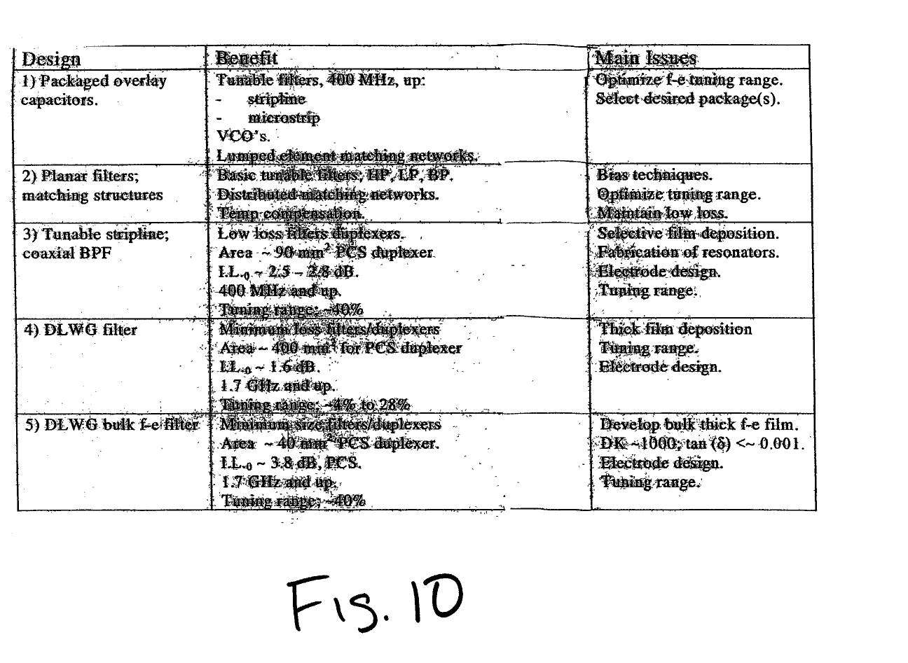

The structure of the resonators is not limited to that shown in FIGS. 2-6. Any resonator structure where an f-e film is coupled to the transmission medium is contemplated by the invention. For instance, instead of being mounted within the resonator as shown in FIG. 5, the f-c film could be mounted on one or more outside surface of the coaxial or stripline resonator similarly to the arrangement shown in FIG. 4 for the DLWG resonator. Likewise, the f-e layers need not be limited to coupling apertures of the DLWG shown in FIG. 4. Instead, f-e film can be deposited on the I/O (Input/Output) surfaces on the waveguide as well as on one or more surfaces on the outside. Additionally, instead of using just one overlay capacitor as shown in FIG. 6, two or more overlay capacitors can be used at either or both ends of the resonator. FIG. 10 is a table generally illustrating some of the design options, benefits and issues associated with a variety of f-e device designs. Designs 3, 4, and 5 generally range from minimum insertion loss, maximum size to minimum size maximum insertion loss.

It can thus be appreciated that the objectives of the present invention have been fully and effectively accomplished. The foregoing specific embodiments have been provided to illustrate the structural and functional principles of the present invention and is not intended to be limiting. To the contrary, the present invention is intended to encompass all modifications, alterations, and substitutions within the spirit and scope of the appended claims.

1. A tunable bandpass filter with a passband, comprising:
at least one resonator having a reactance with a characteristic resonant frequency;
a ferroelectric film having a dielectric constant with a value that changes with an applied electric field, the ferroelectric film being electrically coupled to the resonator so that the reactance of the resonator and therefore the resonant frequency of the resonator and the passband of the filter depend on the dielectric constant of the ferroelectric film; and
an electric field generating device for generating relatively constant electric fields of different strengths, the electric field generating device being constructed and arranged to generate relatively constant electric fields within the ferroelectric film, thereby making the resonant frequency of the resonator and the passband of the filter functions of the strength of the relatively constant electric field.

2. A tunable bandpass filter according to claim 1 wherein the bandpass filter has a filter transfer function, and wherein there are multiple resonators each having a resonator transfer function, and wherein the resonators are electrically coupled such that the filter transfer function is a function of the resonator transfer functions.

3. A tunable bandpass filter according to claim 1 wherein the electric field generating device comprises a dc voltage source connected to two conducting elements in close spaced separation.

4. A tunable bandpass filter according to claim 1 wherein the at least one resonator comprises a dielectric loaded coaxial resonator having a central conductor and an outer conductor.

5. A tunable bandpass filter according to claim 4 wherein the ferroelectric film is mounted between the central conductor and the outer conductor of the resonator.

6. A tunable bandpass filter according to claim 4 wherein the ferroelectric film is mounted outside the outer conductor of the resonator and is overlaid by a conducting medium so as to form at least one overlay capacitor.

7. A tunable bandpass filter according to claim 1 wherein the at least one resonator comprises a dielectric loaded waveguide resonator.

8. A tunable bandpass filter according to claim 7 wherein the ferroelectric film is mounted on an outer surface of the resonator.

9. A tunable bandpass filter according to claim 1 wherein the at least one resonator comprises a stripline resonator having a central conductor, a dielectric substrate and two outer conductors.

10. A tunable bandpass filter according to claim 9 wherein the ferroelectric film is mounted between the central conductor and the dielectric substrate of the at least one resonator.

11. A tunable bandpass filter according to claim 9 wherein the ferroelectric film is mounted outside the outer conductor of the at least one resonator and is overlaid by a conducting medium so as to form at least one overlay capacitor.

12. A tunable bandpass filter according to claim 1 wherein the at least one resonator is at least one microstrip resonator having a microstrip filament layer, a dielectric substrate and a ground plane.

13. A tunable bandpass filter according to claim 12 wherein the ferroelectric film is mounted between the microstrip filament layer and the ground plane.

14. A tunable bandpass filter according to claim 12 wherein the ferroelectric film is mounted outside the ground plane of the resonator and is overlaid by a conducting medium so as to form at least one overlay capacitor.

15. A tunable bandpass filter according to claim 1 wherein the bandpass filter has a filter transfer function, and wherein there are multiple resonators, each resonator comprising a stripline resonator with a resonator transfer function, and wherein the stripline resonators are electromagnetically coupled within an interdigitated topology such that the filter transfer function is a function of the resonator transfer functions.

16. A tunable bandpass filter according to claim 1 wherein the bandpass filter has a filter transfer function, and wherein there are multiple resonators, each resonator comprising a stripline resonator with a resonator transfer function, and wherein the stripline resonators are electromagnetically coupled within a combline topology such that the filter transfer function is a function of the resonator transfer functions.

17. A tunable bandpass filter according to claim 1 wherein the bandpass filter has a filter transfer function, and wherein there are multiple resonators, each resonator comprising a microstrip resonator with a resonator transfer function, and wherein the microstrip resonators are electromagnetically coupled within an interdigitated topology such that the filter transfer function is a function of the resonator transfer functions.

18. A tunable bandpass filter according to claim 1 wherein the bandpass filter has a filter transfer function, and wherein there are multiple resonators, each resonator comprising a microstrip resonator with a resonator transfer function, and wherein the microstrip resonators are electromagnetically coupled within a combline topology such that the filter transfer function is a function of the resonator transfer functions.

19. A tunable bandpass filter according to claim 10 wherein the bandpass filter has a filter transfer function, and wherein there are multiple resonators each having a resonator transfer function, and wherein the resonators are electromagnetically coupled such that the filter transfer function is a function of the resonator transfer functions.

20. A tunable bandpass filter according to claim 11 wherein the bandpass filter has a filter transfer function, and wherein there are multiple resonators each having a resonator transfer function, and wherein the resonators are electromagnetically coupled such that the filter transfer function is a function of the resonator transfer functions.
